(19) United States
(12) Patent Application Publication
(10) Pub. No.: US 2009/0295730 A1
(43) Pub. Date: Dec. 3, 2009

(54) VIRTUAL OPTICAL INPUT UNIT AND CONTROL METHOD THEREOF

(76) Inventors: Yun Sup SHIN, Seoul (KR); Yung Woo Jung, Seoul (KR); Young-Hwan Joo, Seoul (KR)

Correspondence Address: BIRCH STEWART KOLASCH & BIRCH, PO BOX 747, FALLS CHURCH, VA, 22040-0747, US

(21) Appl. No.: 12/364,179

(22) Filed: Feb. 2, 2009

(30) Foreign Application Priority Data
Jun. 2, 2008 (KR) 10-2008-0051472
Jul. 16, 2008 (KR) 10-2008-0069314

(51) Int. Cl. G06F 3/02; H03M 11/00; H04M 1/00

(52) U.S. Cl. 345/168; 341/31; 455/566

(57) ABSTRACT

Provided are an input unit and a control method thereof. In an embodiment of the method, a portion of an input member such as a finger, and a portion of a shadow of the input member generated by a light source are perceived through image processing. Relationship information between the image and shadow of the input member are used, so as to determine if an input is made. Also, the input pattern can be provided to a user using an imaging light, whereas the images can be detected using a detection light.

### CROSS-REFERENCE TO RELATED APPLICATIONS

The present application claims priority under 35 U.S.C. §119 and 35 U.S.C. §365 to Korean Patent Application Nos. 10-2008-0051472 (filed on Jun. 2, 2008) and 10-2008-0069314 (filed on Jul. 16, 2008), which are hereby incorporated by reference in its entirety.

### BACKGROUND

The present disclosure relates to a virtual optical input unit and a control method thereof.

With recent development of semiconductor technology, information communication apparatus has made much progress. Also, due to an information transmitting method of the information communication apparatus, an intuitive and efficient information transmitting method through characters and position information has increased in related art information communication apparatuses that have depended on simple voice signal transmission.

However, since an input unit and an output unit of the information communication apparatus should be directly manipulated or recognized by a user, there is a limit in miniaturization and mobility.

Examples of an input unit of a conventional information communication apparatus include a microphone for voice signals, a keyboard for inputting a specific key, and a mouse for inputting position input information.

Particularly, the keyboard and the mouse are useful input units for efficiently inputting a character or position information. However, since these units are poor in portability and mobility, substitutions for such units are under development.

As the substitution units, a touch screen, a touchpad, a pointing stick, and a simplified keyboard arrangement are being studied, but these units have a limitation in operability and recognition.

### SUMMARY

Embodiments provide a virtual optical input unit which allows miniaturization of a structure and low power consumption so that it can be mounted inside a mobile communication apparatus, and which is not restricted to being used on a flat surface. Embodiments also provide a control method of such input unit.

Embodiments also provide an input unit and a control method thereof, which address the limitations and disadvantages associated with the related art.

Furthermore, embodiments provide a mobile terminal or other portable device including an input unit that allows a user input using shadow information associated with the user input.

In one embodiment, an input unit includes: a pattern generator outputting generation light and detection light from different light sources, respectively, to generate an input pattern; an image receiver capturing and receiving a shadow image of an input member contacting the detection light and the input pattern; and a controller detecting a position of the shadow image received by the image receiver and controlling a command corresponding to the position to be executed.

In another embodiment, an input method includes: outputting generation light and detection light from different light sources, respectively, and matching them to generate an input pattern; capturing and receiving a shadow image of an input member contacting the detection light and the input pattern; and detecting a position of the input member from the received image to execute a command corresponding to the position.

In further another embodiment, an input unit includes: a pattern generator reflecting generation light and detection light output from different light sources to generate an input interface; an image receiver capturing an image of an input member contacting the detection light and the input interface, and a shadow image generated by the input member; an image processor detecting positions of the input member and a shadow image thereof from the captured image, and calculating a contact position of the input member using the detection light; and a controller controlling a command corresponding to the contact position to be executed.

In still further another embodiment, an input method includes: reflecting generation light and detection light output from different light sources, respectively, to the same position and processing them such that they overlap each other to generate an input interface; capturing an image of an input member contacting the detection light and the input interface, and a shadow image generated by the input member; detecting positions of the input member and the shadow image from the captured image, and calculating a contact position of the input member using the detection light; and executing a command corresponding to the contact position.

In yet further another embodiment, a mobile device includes: a wireless communication unit performing wireless communication with a wireless communication system or another device; a user input unit detecting whether a position related with a portion of an input member and a position related with a portion of a shadow of the input member contact each other using generation light for generating an input pattern and detection light for detecting an input to receive a user's input; a display displaying information; a memory storing the input pattern and a corresponding command; and a controller detecting a position of a shadow image received by an image receiver and controlling a command corresponding to the position to be executed.

According to another embodiment, the present invention provides an input unit comprising: a pattern generator including at least first and second light sources, the first light source configured to generate an imaging light for displaying an input pattern, the second light source configured to generate a detection light; an image receiver configured to receive and process an image of an input member over the input pattern and a shadow image of the input member using the detection light; and a controller configured to perform an operation based on information of the image of the input member and the shadow image processed by the image receiver.

According to another embodiment, the present invention provides an input unit comprising: a pattern generator including first and second light sources respectively generating an imaging light and a detection light, the pattern generator further including a reflecting mechanism for reflecting the imaging light and the detection light, the imaging light displaying an input pattern; an image receiver configured to capture an image of an input member over the input pattern and a shadow image of the input member using the detection light; and a controller configured to determine if the input member falls within a contact range of the input pattern using information of the captured image of the input member and the captured shadow image, and to perform an operation based on the determination result.

According to another embodiment, the present invention provides a mobile device comprising: a wireless communication unit configured to perform wireless communication with a wireless communication system or another device; an input unit configured to receive an input, and including a pattern generator including at least first and second light sources, the first light source configured to generate an imaging light for displaying an input pattern, the second light source configured to generate a detection light, an image receiver configured to receive and process an image of an input member over the input pattern and a shadow image of the input member using the detection light, and a controller configured to perform an operation based on information of the image of the input member and the shadow image processed by the image receiver; a display unit configured to display information including the input received by the input unit; and a storage unit configured to store the input pattern.

According to the present disclosure, a miniaturized virtual optical input unit can be realized.

Also, according to the present disclosure, the number of parts used inside the input unit can be minimized, so that a virtual optical input unit of low power consumption can be realized.

Also, according to the present invention, character inputting with excellent operability and convenience can be realized.

Also, according to the present invention, since the size of a virtual input space is not limited, the virtual input space can be variously used.

Also, since low power consumption and miniaturization are possible, an effective character input method of a mobile information communication apparatus can be developed.

The details of one or more embodiments are set forth in the accompanying drawings and the description below. Other features will be apparent from the description and drawings, and from the claims.

### BRIEF DESCRIPTION OF THE DRAWINGS

FIGS. 1A and 1B are a front view and a side view of a virtual optical input unit, respectively, according to an embodiment.

FIG. 2 is a block diagram of a virtual optical input unit according to an embodiment. FIGS. 3A and 3B are schematic views illustrating different examples of the construction of an optical input pattern generator according to an embodiment.

FIGS. 4A and 4B are views illustrating methods of judging when an input is made using a virtual optical input unit according to an embodiment.

FIGS. 5A and 5B are a front view and a side view of a virtual optical input unit, respectively, according to an embodiment.

FIG. 6 is a view illustrating an input unit according to another embodiment.

FIG. 7 is a view illustrating an example of the construction of an input pattern generator in an input unit according to an embodiment.

FIGS. 8A and 8B are views illustrating different examples of the construction of an input pattern generator according to another embodiment.

FIG. 9 is an example of markers for explaining a method of matching an imaging light with a detection light according to an embodiment.

FIG. 10 is a flowchart illustrating an input method according to an embodiment.

FIG. 11 is a view illustrating a pattern generator according to another embodiment.

FIGS. 12A and 12B are views illustrating a mobile device including an input unit according to an embodiment.

FIG. 13 is a block diagram of a mobile device according to an embodiment.

FIG. 14 is a block diagram of a CDMA wireless communication system to which the mobile device of FIG. 13 can be applied.

### DETAILED DESCRIPTION OF THE EMBODIMENTS

Reference will now be made in detail to the embodiments of the present invention, examples of which are illustrated in the accompanying drawings. A virtual optical input unit of the present invention is also referred to simply as the input unit, and a virtual optical input pattern is also referred to simply as the input pattern, in the descriptions of the invention.

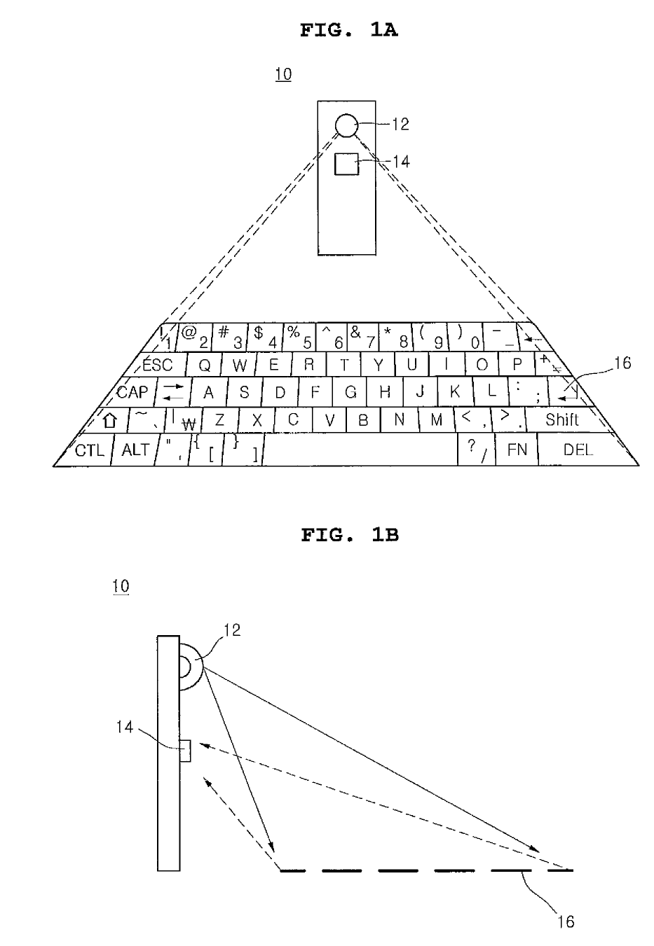

FIGS. 1A and 1B are a front view and a side view of a virtual optical input unit, respectively, according to an embodiment of the invention.

Referring to FIGS. 1A and 1B, the input unit according to an embodiment includes an optical input pattern generator 12 for generating an input pattern, and an image receiver 14 for capturing an image. The input unit can be provided in a mobile terminal such as a PDA, a smart phone, a handset, etc., and all the components of the input unit are operatively coupled and configured.

When a light formed in the shape of a predetermined pattern is emitted from the optical input pattern generator 12, a virtual optical input pattern 16 is generated on a lower surface (which can be any surface). Though FIG. 1 exemplarily illustrates that a keyboard-shaped input pattern is formed, the present invention is not limited thereto and includes various types of input patterns that can replace a mouse, a touchpad, and other conventional input units. For example, an image of the input pattern projected by the input pattern generator 12 may be an image of a keyboard, a keypad, a mouse, a touchpad, a menu, buttons, or any combination thereof, where such image can be an image of any input device in any type or shape or form.

Also, an ‘input member’ in the present disclosure includes all devices used for performing a predetermined input operation using the virtual optical input unit. Preferably, the input member includes a human finger, but can include other objects such as a stylus pen depending on embodiments.

Further, the image receiver 14 is separated by a predetermined distance from the optical input pattern generator 12, and is disposed below the input pattern generator 12. The image receiver 14 captures the projected virtual optical input pattern, the input member (e.g., a user's finger over the projected input pattern), and a shadow image of the input member.

The image receiver 14 may be disposed below the optical input pattern generator 12 so that an image corresponding to a noise is not captured.

The image receiver 14 preferably has an appropriate frame rate in order to capture the movement of the input member and determine whether the input member has made an input (e.g., whether or not the input member contacts the displayed input pattern). For example, the image receiver 14 can have a rate of about 60 frames/sec.

If a user makes an input to the virtual optical input unit, an image captured by the image receiver 14 is processed and identified by an image processor of the input unit to include the virtual input pattern (e.g., projected keyboard image), the input member (e.g., user's finger over the keyboard image), and the shadow image of the input member. The image processor detects the positions of the input member and the shadow and executes a command corresponding to a contact point of the input member. For instance, the image processor analyzes the positions of the input member and shadow in the captured image, determines which part of the displayed input pattern the input member has contacted, and executes a command corresponding to the selection of that part of the displayed input pattern.

A method of identifying, in the image processor of the input unit, each object from the received image, and a method of judging, by the image processor, whether the input member has made a contact will be described later according to an embodiment of the invention.

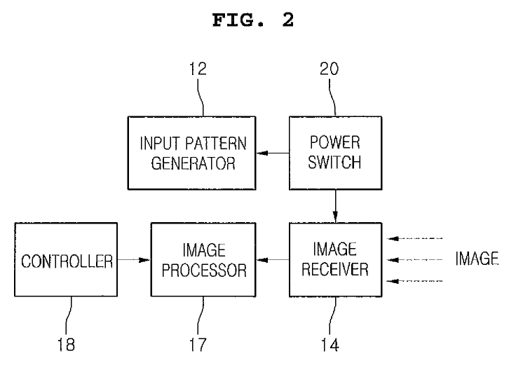

FIG. 2 is a block diagram of a virtual optical input unit according to an embodiment. The input unit in FIGS. 1A and 1B and in any other figures of the present disclosure can have the components of the input unit of FIG. 2.

Referring to FIG. 2, the input unit includes an input pattern generator 12, an image receiver 14, an image processor 17, and a controller 18. All components of the input unit of FIG. 2 are operatively coupled and configured.

The elements 12 and 14 of FIG. 2 can be the same as the elements 12 and 14 of FIGS. 1A and 1B. For instance, the input pattern generator 12 generates a virtual optical input pattern (e.g., an image of a keyboard, keypad, etc.) as discussed above. The image receiver 14 (e.g., a camera) captures the input pattern projected by the input pattern generator 12, a portion of an input member, and a shadow image corresponding to the portion of the input member. For instance, the image receiver 14 may have a preset range of an area that the image receiver 14 is responsible for, and any image that falls within the preset range can be captured by the receiver 14.

The image processor 17 then receives the captured image from the receiver 14 and processes it. For example, the image processor 17 detects a position related with the portion of the input member and the portion of the shadow image, from the captured image received by the image receiver 14. The image processor 17 determines a contact point of the input member (e.g. a point on the input pattern that the input member contacted) based on the detected position information, and generates and/or executes a command corresponding to the contact point of the input member. The controller 18 controls the image processor 17 to execute the command corresponding to the contact point when the portion (e.g., a tip of the finger or stylus) of the input member contacts a part of the input pattern. The controller 18 can control other components and operations of the input unit.

The input unit of the present invention can further include a power switch 20 for turning on and off the input unit. In such a case, the input pattern generator 12 and the image receiver 14 may be selectively turned on and off under control of the power switch 20. As a variation, the input unit may be turned on and off in response to a control signal from a controller included in the mobile terminal or other device having the input unit therein.

Referring to FIG. 3A illustrating one example of the input pattern generator 12, the input pattern generator 12 can include a light source 22 for emitting a light, a lens 24 for condensing the light emitted from the light source 22, and a filter 26 for passing the light emitted from the lens 24. The filter 26 includes a filter member or a pattern for forming the input pattern.

As a variation to FIG. 3B, the filter 26 can be located between the light source 22 and the lens 24 to generate an input pattern.

Examples of the light source 22 include various kinds of light sources such as a laser diode (LD), a light emitting diode (LED), etc. Light emitted from the light source 22 passes through the lens 24 and the filter 26 (in any order) to generate an image of a specific pattern, e.g., in a virtual character input space. The light source 22 is configured to emit a light having intensity that can be visually perceived by a user.

Depending on an embodiment, the light source 22 can be divided into a generation light source for generating a visible light pattern that can be perceived by a user (e.g., for projecting an in put pattern), and a detection light source for generating an invisible light for detecting a contact by the input member.

The lens 24 can be a collimate lens and allows a light incident thereto to be visually perceived by a user and magnifies, corrects, and reproduces in a size that can be sufficiently used by the input member.

The filter 26 is, e.g., a thin film type filter and includes a pattern corresponding to a virtual optical input pattern to be formed. For example, a SLM (spatial light modulator) filer may be used as the filter 26 for projecting different types of images including different types of input patterns.

The image receiver 14 captures and receives the virtual optical input pattern generated by the optical input pattern generator 12, a portion of the input member, and a shadow corresponding to the portion of the input member as discussed above.

The image receiver 14 can be implemented using a camera module and can further include a lens at the front end of the image receiver 14 in order to allow an image to be formed on a photosensitive sensor inside the camera module. A complementary metal oxide semiconductor (CMOS) type photosensitive sensor can control a shooting speed depending on a shooting size. When the CMOS type photosensitive sensor is driven in a low resolution mode at a level that allows shooting of a human finger operation or speed, information required for implementing the present disclosure can be obtained.

The image processor 17 identifies the virtual optical input pattern, a portion of the input member, and a corresponding shadow image from the image received by the image receiver 14, and detects the positions of the portions of the input member and the shadow thereof or positions related thereto to execute a command corresponding to the contact point of the portion of the input member.

If the image processor 17 judges that the portion of the input member contacts the virtual optical input pattern projected on a surface, the controller 18 controls the image processor 17 to execute the command corresponding to the contact point.

Therefore, since the virtual optical input unit according to the present invention is composed of a small number of parts, the size and costs of the input unit can be reduced.

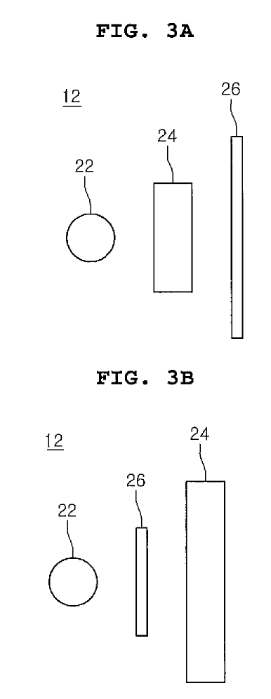

FIGS. 4A and 4B are views illustrating methods of judging whether an input is made by an input member using a virtual optical input unit according to an embodiment of the present invention. These methods of the present invention are preferably implemented using the various examples of the input unit of the present invention, but may be implemented by other suitable input units.

Particularly, FIGS. 4A and 4B are views illustrating different methods of judging when an input member 28 (e.g., finger, stylus, pen, etc.) falls within a contact range of the input pattern to determine if an input is made. The contact range of the input pattern can be set to cover only a direct contact of the input member 28 on the input pattern, or to cover both the direct contact of the input member 28 and positioning of the input member 28 over the input pattern within a preset distance therebetween. For example, the input unit can be set such that it decides that an input is made if the input member 28 contacts the input pattern, or as a variation if the input member 28 is positioned closely (within a preset distance) over the input pattern.

As shown in FIG. 4A, a determination of whether the input member 28 falls within a contact range of the input pattern (i.e., whether an input is made by the input member) can be made using a distance difference (d or l) between a portion of the input member 28 and a shadow 30 of the portion of the input member 28 calculated from the captured image. In another example as shown in FIG. 4B, the same determination can be made using an angle difference θ between the portion of the input member 28 and the shadow 30 generated by the portion of the input member 28 from the captured image.

The light source 22 is part of the optical input pattern generator 12 of FIG. 2, 3A and/or 3B. The lens 24 or the filter 26 of the optical input pattern generator 12 (shown in FIGS. 3A and 3B) is provided, but not shown, in FIGS. 4A and 4B for the sake of brevity. The image receiver 14 separated by a predetermined distance below the optical input pattern generator 12 (i.e., the light source 22) captures an image of an input pattern, an image of the input member 28, and corresponding shadow image 30 (e.g., shadow of the input member 28). Next, the image processor (e.g., image processor 17 in FIG. 2) of the input unit identifies the input pattern, the image of the input member 28, and the corresponding shadow image 30 from the image captured by the image receiver 14, and determines the positions (e.g., distance, angle, etc.) of these respective objects.

According to an embodiment, the image processor can judge whether the input member 28 contacts the input pattern projected on some surface by detecting the portion of the input member 28 and the portion of the corresponding shadow 30, or the positions related thereto.

For example, the image processor can continuously detect the position of the end 28/ of the input member 28 and the position of the end 30′ of the shadow 30 from the image received from the image receiver 14.

If the input member is a finer for example, the image processor can detect the position(s) of a finger tip of the input member 28 and/or the shadow 30 in order to judge a contact of the input member 28 (i.e., whether an input has been made by the input member).

Also, depending on an embodiment, positions offset by a predetermined distance from the ends 28′ and 30′ of the input member 28 and the shadow 30 can be detected and used for judging a contact of the input member 28 (e.g., whether or not the input member 28 contacts the input pattern, or whether or not the input member 28 comes close to the input pattern).

Also, according to the present disclosure, whether the input member 28 contacts or sufficiently comes close to the project input pattern can be judged on the basis of variables changing as the input member 28 comes close to the input pattern surface such as angle relation, a relative velocity, and/or a relative acceleration besides the distance relation between the positions related with the portion of the input member 28 and the shadow 30 thereof.

Although a case of using position information of the end 28′ of the input member 28 and the end 30′ of the shadow 30 is discussed in FIGS. 4A and 4B, the above-described various reference values (e.g., relative velocity, relative acceleration, etc.) can be used in order to judge whether the input member contacts or sufficiently comes close to the projected input pattern.

Since the technologies for identifying an object from a captured image are well known to those of ordinary skill in the art, the detailed description thereof is omitted for the sake of brevity

Also, since the technologies for identifying an object from an image captured through image processing and finding out a boundary line using, e.g., a brightness difference between adjacent pixels are also well known to and widely used by those of ordinary skill in the art, some descriptions of image processing methods used for calculating the positions of a portion of the input member 28 and the portion of the shadow image 30, or positions related thereto are omitted. All these known technologies can be used in the present invention.

In the example of FIG. 4A, a distance difference between the end 28′ of the input member 28 and the end 30′ of the shadow 30, or a distance difference between positions related with the input member 28 and the shadow 30 is continuously calculated by the image processor of the input unit. When the calculated distance difference is 0 (which indicates a direct contact of the input member on the input pattern) or some value that falls within a preset range (which indicates that the input member is positioned close enough to the input pattern), it can be judged that the input member 28 falls within a contact range of the input pattern and that an input is made by the input member 28. Depending on an embodiment, when the calculated distance difference becomes a predetermined threshold value or less, it can be judged that the input member 28 contacts the input pattern.

At this point, even in a case of detecting another portion related with the input member 28 or the shadow 30 instead of the ends 28′ and 30′ of the input member 28 and the shadow 30, a point when a distance between other portions related with the input member 28 and the shadow 30 is 0 or a predetermined threshold value or less can be detected. For example, instead of using the ends 28′ and 30′ to determine the positional relationship between the input member 28 and the shadow 30, other parts of the input member 28 and the shadow 30 may be used to make this determination.

Also, depending on an embodiment, even in the case where the input member 28 does not actually contact the surface (input pattern), when the input member 28 comes close within a predetermined distance from the input pattern, the image processor of the input unit can judge that the input member contacts the input pattern (an input is made).

The distance between the input member and its shadow can be judged using a straight line distance l between the end 28′ of the input member 28 and the end 30′ of the shadow, or using a horizontal distance d between a corresponding position of the input member end 28/downwardly projected on the surface and the shadow end 30′.

According to another example, an angle θ between the input member end 28, and the shadow end 30′ is calculated to determine whether the input member end 28′ falls within the contact range of the input pattern (i.e., whether an input is made) as illustrated in FIG. 4B. Depending on an embodiment, the contact of the input member can be judged by judging whether or not the input member end/part falls within the contact range on the basis of an angle between portions related with the input member 28 and the shadow 30.

Referring to the left drawings of FIGS. 4A and 4B, when the input member 28 does not contact the input pattern, the distance l or d between the input member end 28′ and the shadow end 30′ has a non-zero value, or the angle θ between the input member end 28′ and the shadow end 30′ has a non-zero value.

However, when the input member 28 contacts the input pattern, the above values l, d, and θ become zero, and thus using these values, it can be judged that the input member 28 has contacted the input pattern.

As described above, depending on an embodiment, when each of the above values l, d, and θ becomes a predetermined threshold value or less, it can be judged that the input member 28 contacts the input pattern.

As described above, when the input member 28 comes close within a predetermined distance to the input pattern even though a contact of the input pattern does not actually occur, the input member can be judged to be in contact with the input pattern and a subsequent process can be performed.

When the input member 28 contacts the input pattern such as the virtual keyboard image (16), plane coordinates corresponding to the contact point can be calculated through the image processing by analyzing the image captured by the image receiver. That is, by determining the exact contact location on the input pattern, a user's specific input (e.g., selecting a letter “K” on the keyboard image 16) can be recognized. When the controller of the input unit orders a command corresponding to the coordinates of the contact point to be executed, the image processor (or other applicable components in the input unit or the mobile device) executes the command.

According to an embodiment, as a reference for judging a contact of the input member 28, the relative velocities and/or accelerations of the input member end 28′ and the shadow end 30′ can also be used.

For example, when the relative velocities of the input member end 28′ and/or the shadow end 30′ are zero, the image processor can judge that the positions of the two objects are fixed. Assuming that a direction in which the input member end 28′ and the shadow end 30′ come close is a (+) direction, and a direction in which the input member end 28′ and the shadow end 30′ move away is a (−) direction, when the relative velocity has a (+) value, the image processor can judge that the input member 28 comes close to the input pattern. On the other hand, when the relative velocity has a (−) value, the image processor can judge that the input member 28 moves away from the input pattern.

That is, a relative velocity is preferably calculated from continuously-shotimages over continuous time information when the relative velocity changes from a (+) value to a (−) value in an instant, it is judged that a contact occurs. Also, when the relative velocity has a constant value, it is judged that a contact occurs.

Also, acceleration information is continuously calculated, and when an (−) acceleration occurs in an instant, it is judged that a contact occurs. At the point of contact, the acceleration will change instantly, which can be detected as a contact occurrence.

As a variation, instead of using the input member end and the shadow end, the relative velocity information or acceleration information of other portions of the input member 28 and the shadow 30 or other positions related thereto can be calculated and used to determine if an input is made by the input member 28.

To realize a computer algorithm on the basis of the above-described technology, continuous time information (that is, continuous shot images) is used. For this purpose, a construction that can constantly store and perform an operation on extracted information may be provided,

Therefore, for this purpose, image processing of an image received by the image receiver 14 is used. For example, images can be extracted over three continuous times t₀, t₁, and t₂, and a velocity and/or an acceleration can be calculated on the basis of the extracted images. Also, the continuous times t₀, t₁, and t₂ may be constant intervals.

Judging a contact of the input member 28 (e.g., whether or not the input member falls within the contact range of the input pattern) using the velocity information and/or the acceleration information can be used as a method of complementing a case where the calculation and use of the distance information or the angle information may not be easy or appropriate.

Accordingly, a determination of whether or not an input is made (i.e., whether or not a portion of the input member falls within a contact range of the input pattern) can be made by determining relationship information between an image of the portion of the input member and an image of the corresponding shadow. The relationship information can include at least one of the following: a distance between the portion of the input member and the portion of the shadow of the input member; a distance between a point on the input pattern that corresponds to the portion of the input member, and the portion of the shadow of the input member; an angle between the portion of the input member and the portion of the shadow of the input member; a velocity or acceleration of the input member; and a velocity or acceleration of the shadow of the input member. The relationship information can be used by any input unit of the invention including the input units discussed below.

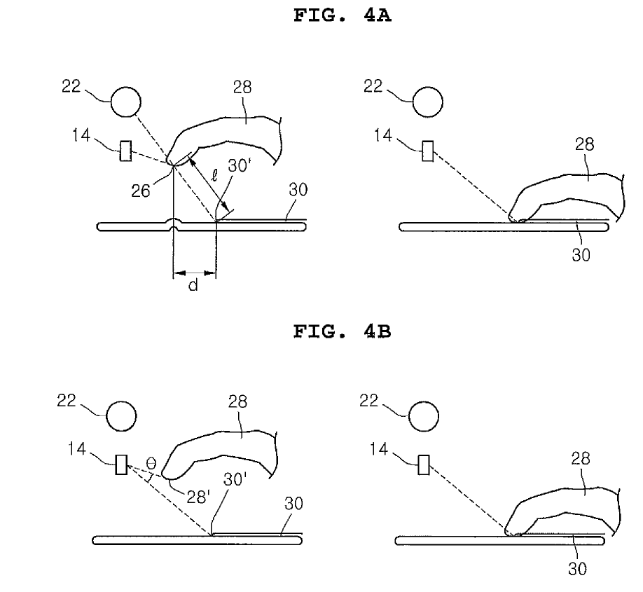

FIGS. 5A and 5B are a front view and a side view of a virtual optical input unit, respectively, according to an embodiment of the present invention.

Referring to FIGS. 5A and 5B, the virtual optical input unit includes an input pattern generator 310 and an image receiver 314. The components of the input unit are operatively coupled and configured. A light in a predetermined pattern is emitted from the input pattern generator 310, so that an interface 320 is displayed on a surface

Here, a keyboard-shaped input interface is shown as a non-limiting example, and thus the interface 320 is not limited thereto but various shapes, sizes, configurations of different input patterns can be generated and displayed by the input pattern generator 310.

The input pattern generator 310 outputs a generation light 340 and a detection light 350 to generate the input pattern 320. The generation light 340 is also referred to herein as an imaging light since it projects images including the virtual optical input patterns. The input pattern generator 310 can include a single light source for generating a light which may be split into multiple light beams for respectively generating the generation light 340 and the detection light 350, or can include multiple light sources for respectively generating the generation light 340 and the detection light 350.

Specifically, the input pattern 320 of a predetermined pattern that can be visually perceived by a user is projected using the imaging light 340. For example, the keyboard pattern of FIG. 5A can be generated. The detection light 350 is output in order to generate a detection region that can analyze an input such as a contact by the input member without being visible to the user, and can overlap the input pattern 320.

The image receiver 314 is separated by a predetermined distance from the input pattern generator 310, and captures a shadow image of the input member over the input pattern.

Here, the input member includes all means used for providing a predetermined input to the input interface. Generally, the input member includes a human finger and can include other objects such as a pen, a stylus pen, etc. depending on an embodiment.

The input unit of FIGS. 5A and 5B includes other components. For example, the input unit can have the structure of FIG. 2. For instance, the input unit can include the power switch 20, the image processor 17, and the controller 18 that communicate with the input pattern generator 310 and the image receiver 314.

The image receiver 314 preferably has a frame speed of an appropriate rate in order to capture the movement of the input member and judge a contact by the input member. For example, the image receiver 314 can be configured to capture images at an interval of about 60 frames/sec.

Also, an image captured by the image receiver 314 is transmitted to the image processor 17. The image processor 17 identifies the input interface (e.g., the input pattern), the input member, and the shadow image of the input member, and detects the positions of the input member and the shadow thereof to process the image such that the coordinates of a point at which the input member contacts or comes close to the input pattern are calculated.

Here, the image receiver 314 can be implemented using an infrared camera module, and can further include a lens at the front end of the image receiver 314 in order to allow an image to be formed on a photosensitive sensor inside the camera module.

According to an embodiment of the present invention, light sources are individually controlled by separately outputting the imaging light and the detection light. Accordingly, the input interface is output using the light that can be conveniently perceived by a user as the imaging light, and the light that is reliable even against the outside light interference and noise is used as the detection light, so that an error generating factor is reduced.

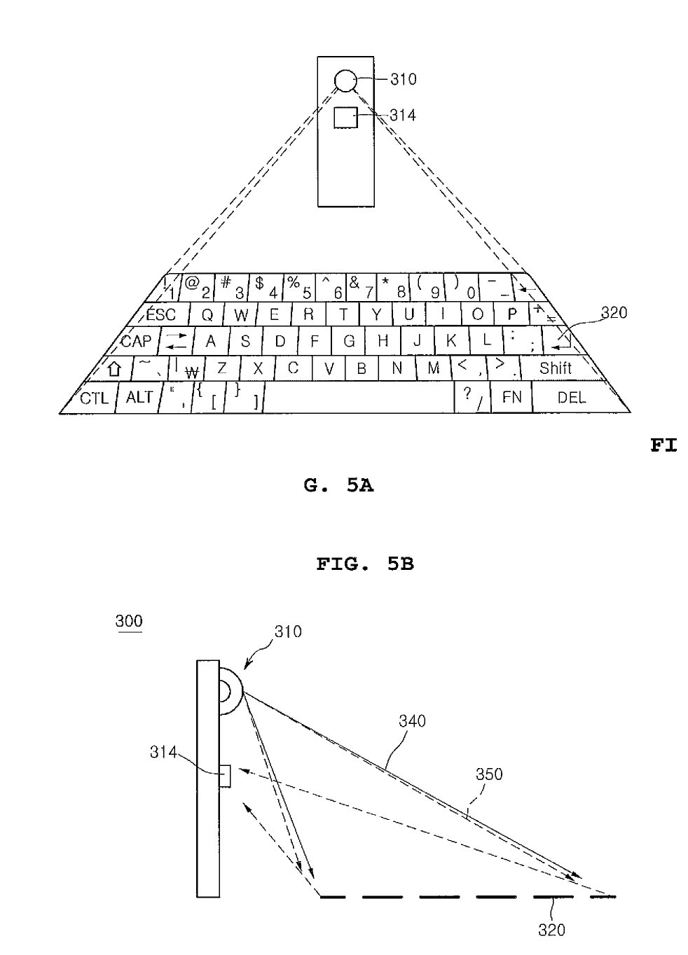

As a non-limiting example, depending on an embodiment, as illustrated in FIG. 6, the input pattern generator 310 can be divided into an imaging light output unit 311 for outputting a light in a visible wavelength band, and a detection light output unit 312 for outputting a light in a non-visible wavelength band.

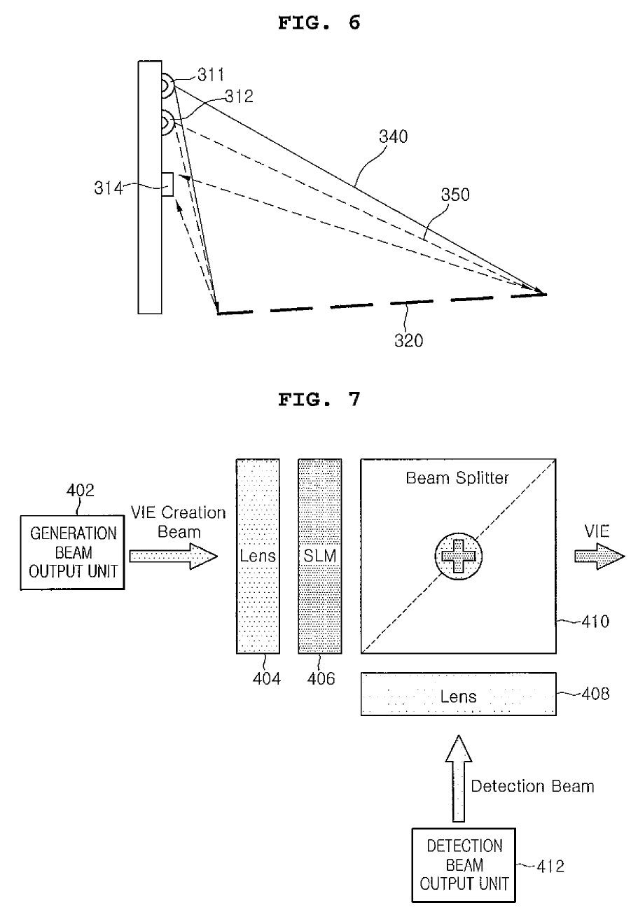

FIG. 7 is a view illustrating an example of the construction of an input pattern generator of the virtual optical input unit according to an embodiment of the invention. The input pattern generator of FIG. 7 can be used as the input pattern generator 310 of FIG. 6.

Referring to FIG. 7, the input pattern generator can include an imaging light output unit (generation beam output unit) 402 for outputting an imaging light, a detection light output unit (detection beam output unit) 412 for outputting a detection light, a lens 404 for condensing the light emitted from the imaging light output unit 402 to transmit the light to a space light modulator (SLM) 406, a lens 408, and a beam splitter 410 for allowing axes of the imaging light and the detection light to coincide with each other. The SLM 406 modulates the received light to generate a certain input pattern, e.g., the input pattern 320. The display of the input pattern may also be dynamically changed.

The imaging light output unit 402 outputs the imaging light (e.g., the imaging light 340) for generating an input pattern. In an example, the imaging light output unit 402 outputs the imaging light using the visible light in a wavelength band that has high recognition and does not harm a human body.

The lens 404 condenses the received imaging light to transmit the light to the SLM 406. The SLM 406 modulates the light to generate an input pattern.

For example, the imaging light (e.g., the imaging light 340) is output and passes through the lens 404. And then, while the light passes through the SLM 406, the polarization condition of the SLM 406 is applied to the light according to a predetermined input pattern, so that the light is displayed in the shape of the predetermined input pattern (VIE : Virtual Input Environment pattern) in a virtual space.

Here, the input pattern displayed in the virtual space can be changed into various shaped patterns and/or various sizes such as a keyboard shape, a keypad pattern, a mouse pattern, etc.

Also, as non-limiting examples, the SLM 406 can be a transmissive SLM such as Thin Film Transistor Liquid Crystal (TFT LC), Super Twisted Nematic Liquid Crystal (STN LC) of a passive matrix), ferro Liquid Crystal, Polymer Dispersed Liquid Crystal (PDLC), and Plasma Address Liquid Crystal (PALC).

Further, a virtual input pattern desired by a user can be generated actively using the SLM 406, and therefore, a more active interface can be established in comparison with displaying a pattern of a shape stored in advance.

The detection light output unit 412 outputs the detection light (e.g., the detection light 350) for detecting a user's input of contacting (or coming close enough) the input pattern. In an example, the detection light output unit 412 outputs, as the detection light, a light in an infrared (TR) wavelength band of invisible light that is less influenced by an outside light interference factor.

The lens 408 condenses the detection light from the detection light output unit 412 to output the light to the beam splitter 410.

The beam splitter 410 receives the imaging light and the detection light and processes them such that the axes of the imaging light and the detection light coincide with each other, thereby generating a virtual input pattern.

Each of the imaging light output unit 402 and the detection light output unit 412 can include one or more light sources. Examples of the light sources include various kinds of light sources such as a laser diode (LD), a light emitting diode (LED), etc.

As described above, the imaging light and the detection light can be individually controlled and the output positions thereof can be made different by allowing the imaging light and the detection light to be output from different light sources, respectively. Therefore, the detection light output unit together with the image receiver can output a light and receive an image in a place with less influence from the outside light interference.

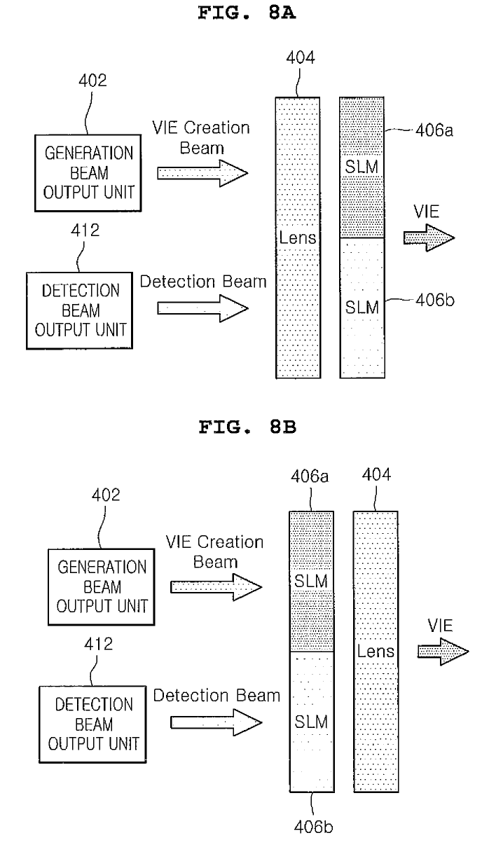

FIGS. 8A and 8B are views illustrating different examples of the construction of an input pattern generator according to another embodiment. Here, the input unit includes the same or similar components as the input unit of FIGS. 6 and/or 7 while the structure of the input pattern generator may vary as shown in FIG. 8A or 8B. The input pattern generator in each of FIGS. 8A and 8B includes an imaging light output unit 402, a lens 404, a detection light output unit 412, and SLMs 406a, 406b, all operatively coupled and configured. The components 402, 404 and 412 in FIGS. 8A and 8B can be the same as the components 402, 404 and 412 of FIG. 7.

Referring to FIG. 8A, an imaging light and a detection light are horizontally output from the output units 402 and 412 having different wavelength bands, respectively, pass through the lens 404, and are input respectively to the different SLMs 406a and 406b to generate an input pattern.

In case of horizontally outputting the imaging light and the detection light, an interval error may be generated between the light sources outputting the imaging light and the detection light, and the axes thereof may not coincide with each other. To address this concern, when the interval error is measured and stored in advance, the image receiver 17 can compensate for the interval error at a detection position to match the axes with each other at the input pattern by the imaging light when detecting a user's input using the detection light.

In another example, as illustrated in FIG. 8B, the positions of the lens 404 and the SLMs 406a and 406b in FIG. 8A can be switched to generate a virtual input pattern. That is, the lens 404 can be disposed before or after the SLMs 406a/406b. Since the light output units 402 and 412 are disposed parallel to each other and the beam splitter is not used in FIGS. 8A and 8B, the size of the input unit can be reduced.

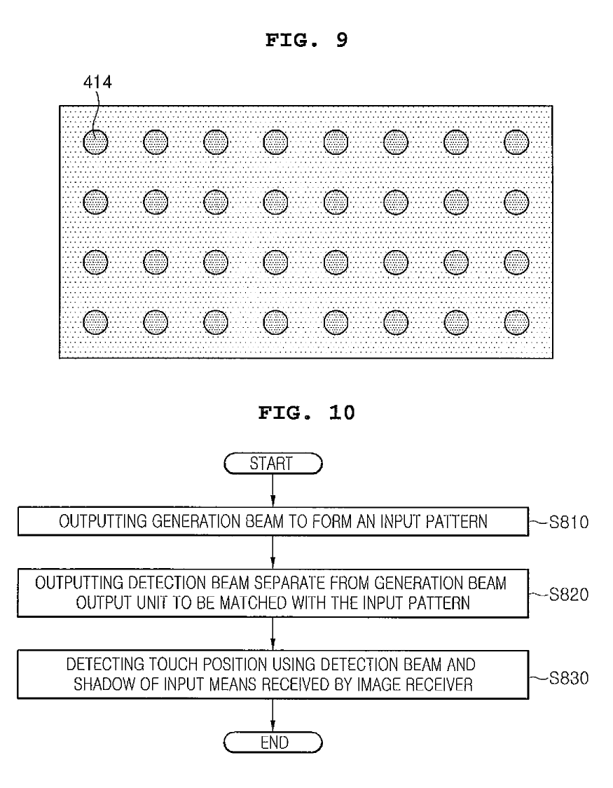

As a non-limiting example, as illustrated in FIG. 9, the detection light is projected by the input pattern generator on the surface so that it overlaps the imaging light. Further, markers 440 are displayed which can be arranged in a grid configuration in order to accurately detect a position at which a user makes an input on the input pattern. Here, the markers in any shape, size or configuration can be used, and can be formed by an invisible or visible light so that the markers may be invisible or visible to the user.

According to an embodiment, for example, in the case where the projected input pattern is a keyboard, the markers 440 can be arranged in a grid configuration in order for the image receiver to more accurately detect a user's input with respect to the detection light.

The intervals and positions of the markers 440 can be stored in advance. For example, each of the markers 440 can be set to match with each pattern, key, or portion of the keyboard (input pattern) to be formed. After that, images received by the image receiver 14 are image-processed to compare the intervals and positions of the captured respective markers 440 with those stored in advance, so that the image processor 17 can determine how much distortion has been generated and an appropriate correction can be then performed. For example, any distortion or irregularities in the markers captured by the image receiver 14 can indicate that the surface onto which the input pattern is projected may have the same distortion or irregularities, which would then be compensated accordingly when the image processor 17 processes and analyzes the captured images. This scheme can be used to enhance the use of the input unit in situations when the input unit is used on non-flat surfaces. Here, the arrangement shape, interval, and size of the marker can be changed depending on an embodiment.

For detecting if an input is made by the input member, there may be two types of input detection: a case where the calculation of the absolute coordinates of the input member is needed (for example, a keyboard), and a case where the calculation of the relative coordinates of the input member is sufficient (for example, a mouse). In the case where the calculation of the absolute/exact coordinates of the input member is needed, the calibration process may be performed. For example, depending on which input pattern is currently projected, the input unit can be set up to variably change its settings so that a proper position calculation may be adaptively performed according to the currently displayed input pattern.

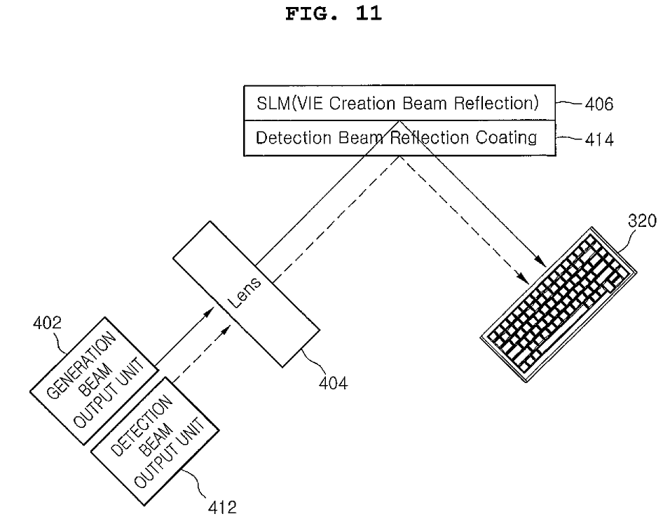

FIG. 10 is a flowchart illustrating an input method according to an embodiment of the present invention. This method can be implemented using various examples of the input unit of the invention discussed herein.

Referring to FIG. 10, an imaging light (generation beam) is output to generate an input pattern (S810). The imaging light can be generated using a light source in a visible wavelength band that can be visually perceived by a user, and can be configured to generate the input pattern in various shapes.

For example, an arbitrary pattern desired by a user can be actively generated using an SLM.

After that, the imaging light outputted from the light source, and a detection light (detection beam) from a separate light source for detecting a position of contact on the input pattern, are formed to match with each other (S820). For example, the detection light is projected on the input pattern to correspond with the input pattern. Here, the markers discussed may also be present.

The detection light can be generated using a light source in an invisible wavelength band invisible to a user's eyes, and used for detecting whether the input member falls within a contact range of the input pattern (e.g., whether the input member contacts the input pattern, whether the input member comes within a preset range of the input pattern, etc. depending on the setup of the input unit).

After that, the image receiver receives the detection light and an image and shadow of the input member (contacting the input pattern or coming close to the input pattern) to detect a contact point (S830).

For example, when the input member contacts the input pattern, the contact point is detected and a command corresponding to the detected position (e.g., a specific input selected by the input member) is executed.

As described above, according to an embodiment of the present disclosure, since the imaging light and the detection light are individually output from separate light sources, the imaging light and the detection light can be individually controlled. The detection light together with the image receiver can be installed to a place having a less outside light interference.

Also, according to the present disclosure, the markers can be arranged in the detection light, so that a position where the input member contacts can be more accurately detected using the markers.

Also, according to the present disclosure, the number of parts used in the inside the input unit can be minimized, so that a miniaturized input unit of low power consumption can be provided.

Also, according to the present invention, various kinds of input patterns can be stored and available in the input unit or the device having the input unit (if desired), and can be selectively projected using the SLM. For examples, information on various input patterns can be prestored in a storage unit associated with the input unit, so that any one of the input patterns can be displayed as needed. The input patterns to be displayed can be selectively changed by the system or user, so that the convenience and more user-friendly input unit can be provided to a user.

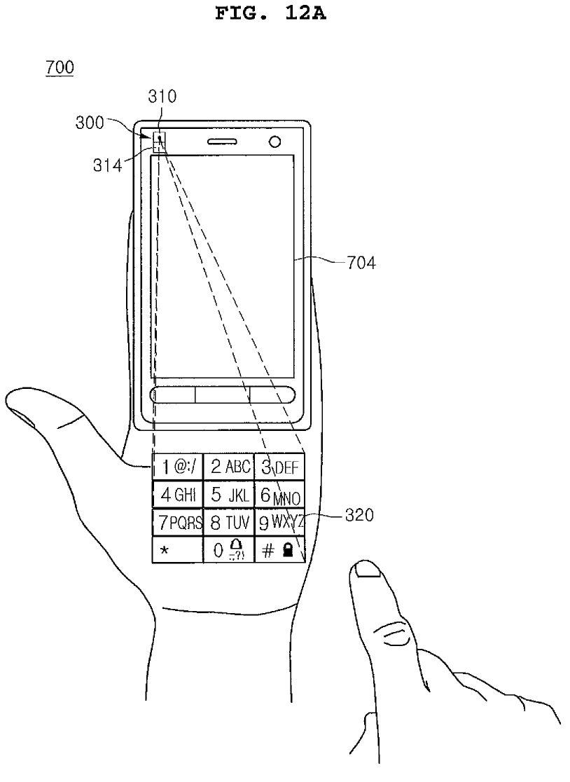

FIG. 11 is a view illustrating a pattern generator usable in any input unit of the invention according to another embodiment of the invention.

Referring to FIG. 11, the pattern generator includes an imaging light output unit (generation beam output unit) 402 for outputting an imaging light (generation beam), a detection light output unit (detection beam output unit) 412 for outputting a detection light (detection beam), a lens 404 for condensing the imaging light and the detection light to transmit them to an SLM 406, the SLM 406 for modulating and reflecting the imaging light to form an arbitrary input interface/pattern, and a reflector 414 installed on a front side of the SLM 406 to reflect the detection light. The imaging light reflected by the SLM 406 forms an input interface 320 (e.g., an optical image of a keyboard) of a predetermined pattern on a surface. The detection light reflected by the reflector 414 overlaps the input interface 320 so that the movement of the input member with respect to the input interface 320 can be detected using the detection light.

The imaging light output unit 402 outputs the imaging light for generating the input interface of a predetermined pattern. The imaging light output unit 402 can output the imaging light using a visible light in a wavelength band that has high recognition and does not harm a human body.

The detection light output unit 412 outputs the detection light for detecting a user's input on the input interface. The detection light output unit 412 can use a light in an infrared (IR) wavelength band of invisible light that is less influenced by an outside light interference factor.

The lens 404 condenses the imaging light and the detection light to transmit them to the SLM 406. The SLM 406 modulates the light to form the predetermined input pattern.

Here, the lens 404 magnifies and corrects the incident light in a size that can be sufficiently used as the input interface. Therefore, the input pattern generated by the imaging light passing through the lens 404, and a detection region generated by the detection light for detecting whether the input member contacts the input pattern may be displayed to overlap each other in the same size or substantially the same size.

Also, a separate lens for condensing the detection light can be further provided, and the detection region can be displayed larger than the input pattern.

In this example, the SLM 406 is implemented in a reflective type for modulating the light to generate the input interface of a predetermined pattern. The reflector 414 for reflecting the light in a specific band is provided on the front side of the SLM 406.

The reflector 414 can be a separate unit independent of the SLM 406, or can be integrally provided by coating a predetermined reflective material on the front side of the SLM 406.

Specifically, in an example, the reflector 414 transmits light in a visible region and reflects light in an invisible region. Therefore, the imaging light condensed by the lens passes through the reflector 414 and impinges the SLM 46, and then is reflected in a specific pattern by the SLM 406 and output as the input pattern 320. On the other hand, the detection light from the lens 404 is reflected by the reflector 414 and thus directly output as the detection region for detecting an input. The detection region (an area illuminated by the detection light) overlaps the input pattern 320.

Here, the markers 440 can be arranged in the detection region of the detection light. The markers 440 can be arranged in a grid configuration in order for the image receiver to more accurately detect a user's input as illustrated in FIG. 9.

The input unit according to embodiments can be mounted or disposed in an electronic device or a mobile device such as a cellular phone, an MP3 player, a computer notebook, and a personal digital assistant (PDA), etc.,

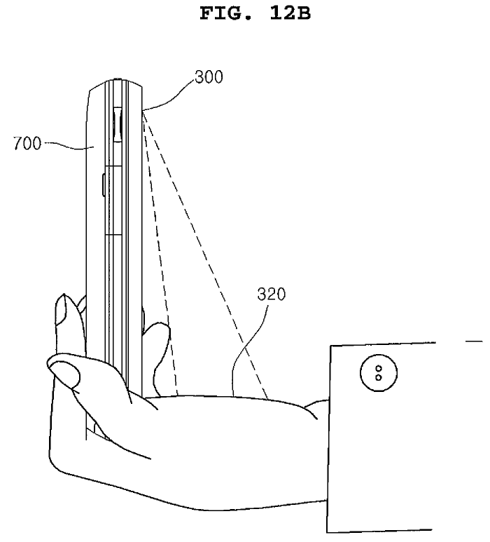

FIGS. 12A and 12B are views illustrating a mobile device 700 to which an input unit 300 according to the invention is provided according to an embodiment of the invention. The input unit 300 can be any input unit discussed above.

FIG. 12A illustrates an example of mounting the input unit 300 in the mobile device 700 to provide an input interface.

For example, when a user takes the mobile device with his one hand, a virtual keypad (optical image of a keypad) 320 is output from the mobile device and displayed on the palm surface of the hand. The user touches the virtual keypad with the other hand (e.g., using a finger or pen) to input any desired input such as numbers and characters.

The input unit 300 includes an input pattern generator 310 which outputs an imaging light and a detection light, such that the keypad and a detection region overlap each other and are displayed on the palm.

At this point, an image receiver 314 (e.g., camera module) of the input unit captures a finger contacting the keypad 320 and a shadow of the finger over the keypad 320 to judge whether the finger contacts the keypad 320 and to calculate and process the coordinates of the contact point. For example, a number and a character of the keypad corresponding to the calculated coordinates are considered to have been inputted to the mobile device by the input member, and processed accordingly. Here, an input made by the input member on the input pattern (e.g., selected input numbers, characters, etc.) can be displayed on a display 704 of the mobile device 700 so that they can be checked by the user.

Here, the input interface is not limited to the above embodiments but various patterns of input interfaces can be output and used by the input unit.

As described above, the size of the input unit can be minimized through the use of the reflective type SLM, so that the input unit can be integrally implemented without limitation on the size of an electronic apparatus including a mobile device to which the input unit can be provided.

Also, according to at least one embodiment, the present invention separately outputs the imaging light and the detection light to individually control the imaging light and the detection light. As a result, the input interface/pattern is output using the imaging light that can be comfortably perceived by a user's eyes as the imaging light, and an error generating factor can be reduced using the detection light that is reliable even against the outside light interference.

Also, according to at least one embodiment of the present invention, the detection region, the input member, and the shadow of the input member are captured using the image receiver, so that the input interface can be displayed on various surfaces including uneven surfaces.

Also, according to at least one embodiment of the present invention, various kinds of input patterns are disposed on one system as necessary using the SLM, and the patterns can be selectively changed by the user or system, so that the convenience is provided to the user.

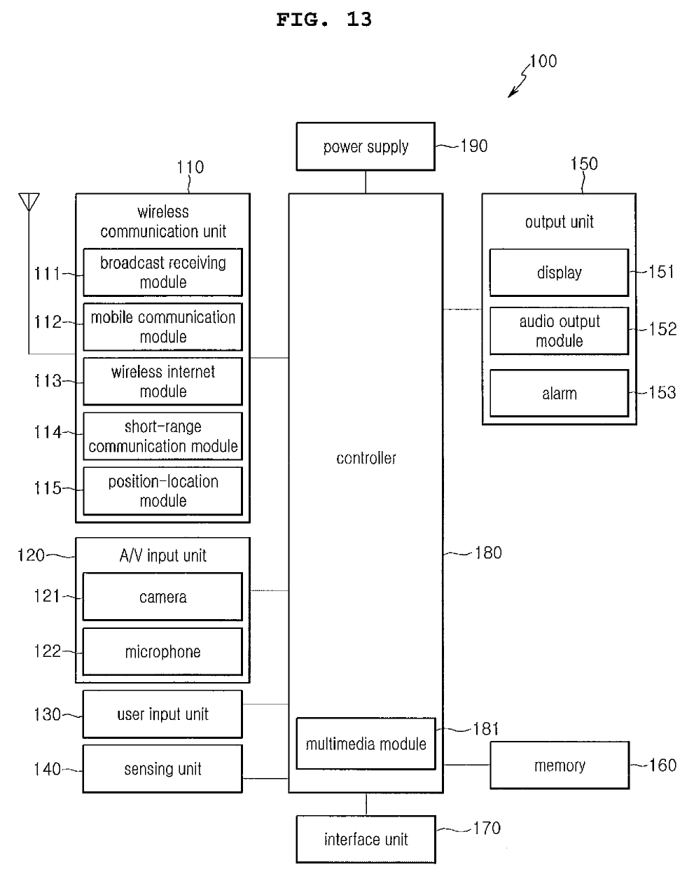

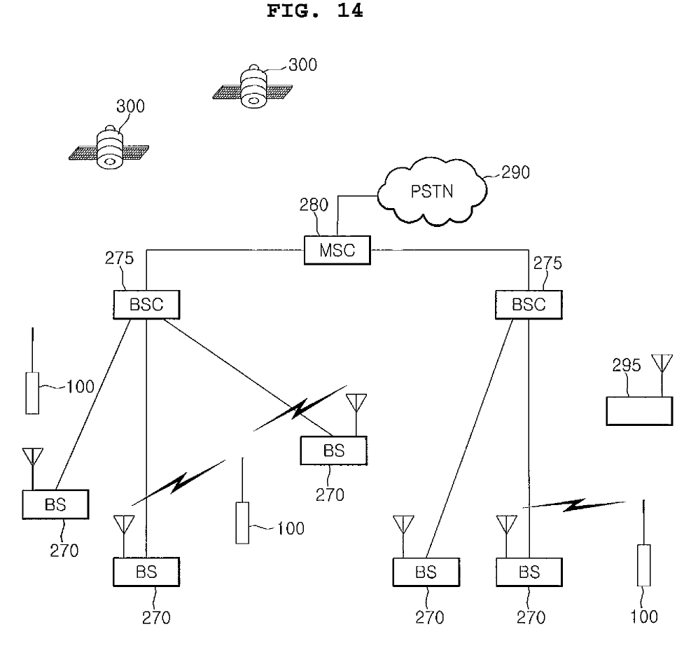

Various embodiments and examples of the input units, methods and operations of the present invention discussed above can be implemented in a mobile device or portable electronic device. An example of such a device as a mobile device 100 is discussed below referring to FIGS. 13 and 14. A controller 180 of the mobile device 100 may be configured to control a display 151 (which may be a touch screen) to perform the various user interface controlling methods of the present invention discussed above. The mobile device of the present invention may have all or part of the components of the mobile device 100.

FIG. 13 is a block diagram of mobile device 100 in accordance with an embodiment of the present invention. The mobile device 100 includes the input unit among various examples discussed above according to the embodiments of the invention. All components of the mobile device are operatively coupled and configured.

The mobile device may be implemented using a variety of different types of devices. Examples of such devices include mobile phones, user equipment, smart phones, computers, digital broadcast devices, personal digital assistants, portable multimedia players (PMP) and navigators. By way of non-limiting example only, further description will be with regard to a mobile device. However, such teachings apply equally to other types of devices. FIG. 13 shows the mobile device 100 having various components, but it is understood that implementing all of the illustrated components is not a requirement. Greater or fewer components may alternatively be implemented.

FIG. 13 shows a wireless communication unit 110 configured with several commonly implemented components. For instance, the wireless communication unit 110 typically includes one or more components which permits wireless communication between the mobile device 100 and a wireless communication system or network within which the mobile device is located.

The broadcast receiving module 11I receives a broadcast signal and/or broadcast associated information from an external broadcast managing entity via a broadcast channel. The broadcast channel may include a satellite channel and a terrestrial channel. The broadcast managing entity refers generally to a system which transmits a broadcast signal and/or broadcast associated information. Examples of broadcast associated information include information associated with a broadcast channel, a broadcast program, a broadcast service provider, etc. For instance, broadcast associated information may include an electronic program guide (EPG)of digital multimedia broadcasting (DMB) and electronic service guide (ESG) of digital video broadcast-handheld (DVB-H).

The broadcast signal may be implemented as a TV broadcast signal, a radio broadcast signal, and a data broadcast signal, among others. If desired, the broadcast signal may further include a broadcast signal combined with a TV or radio broadcast signal.

The broadcast receiving module 111 may be configured to receive broadcast signals transmitted from various types of broadcast systems. By nonlimiting example, such broadcasting systems include digital multimedia broadcasting-terrestrial (DMB-T), digital multimedia broadcasting-satellite (DMB-S), digital video broadcast-handheld (DVB-H), the data broadcasting system known as media forward link only (MediaFLO®) and integrated services digital broadcast-terrestrial (ISDB-T). Receiving of multicast signals is also possible. If desired, data received by the broadcast receiving module 111 may be stored in a suitable device, such as memory 160.

The mobile communication module 112 transmits/receives wireless signals to/from one or more network entities (e.g., base station, Node-B). Such signals may represent audio, video, multimedia, control signaling, and data, among others.

The wireless internet module 113 supports Internet access for the mobile device. This module may be internally or externally coupled to the device.

The short-range communication module 114 facilitates relatively short-range communications. Suitable technologies for implementing this module include radio frequency identification (RFID), infrared data association (IrDA), ultra-wideband (UWB), as well at the networking technologies commonly referred to as Bluetooth and ZigBee, to name a few.

Position-location module 115 identifies or otherwise obtains the location of the mobile device. If desired, this module may be implemented using global positioning system (GUPS) components which cooperate with associated satellites, network components, and combinations thereof.

Audio/video (A/V) input unit 120 is configured to provide audio or video signal input to the mobile device. As shown, the A/V input unit 120 includes a camera 121 and a microphone 122. The camera receives and processes image frames of still pictures or video.

The microphone 122 receives an external audio signal while the portable device is in a particular mode, such as phone call mode, recording mode and voice recognition. This audio signal is processed and converted into digital data. The portable device, and in particular, A/V input unit 120, typically includes assorted noise removing algorithms to remove noise generated in the course of receiving the external audio signal. Data generated by the A/V input unit 120 may be stored in memory 160, utilized by output unit 150, or transmitted via one or more modules of communication unit 110. If desired, two or more microphones and/or cameras may be used.

The user input unit 130 generates input data responsive to user manipulation of an associated input device or devices. Examples of such devices include a keypad, a dome switch, a touchpad (e.g., static pressure/capacitance), a touch screen panel, a jog wheel and a jog switch.

The virtual optical input device according to the embodiments of the present invention can be used as the user input unit 130 or as part of the user input unit 130.

The sensing unit 140 provides status measurements of various aspects of the mobile device. For instance, the sensing unit may detect an open/close status of the mobile device, relative positioning of components (e.g., a display and keypad) of the mobile device, a change of position of the mobile device or a component of the mobile device, a presence or absence of user contact with the mobile device, orientation or acceleration/deceleration of the mobile device.

The sensing unit 140 may comprise an inertia sensor for detecting movement or position of the mobile device such as a gyro sensor, an acceleration sensor etc. or a distance sensor for detecting or measuring the distance relationship between the user's body and the mobile device.

The interface unit 170 is often implemented to couple the mobile device with external devices. Typical external devices include wired/wireless headphones, external chargers, power supplies, storage devices configured to store data (e.g., audio, video, pictures, etc.), earphones, and microphones, among others. The interface unit 170 may be configured using a wired/wireless data port, a card socket (e.g., for coupling to a memory card, subscriber identity module (SIM) card, user identity module (UIM) card, removable user identity module (RUIN) card), audio input/output ports and video input/output ports.

The output unit 150 generally includes various components which support the output requirements of the mobile device. Display 151 is typically implemented to visually display information associated with the mobile device 100. For instance, if the mobile device is operating in a phone call mode, the display will generally provide a user interface or graphical user interface which includes information associated with placing, conducting, and terminating a phone call. As another example, if the mobile device 100 is in a video call mode or a photographing mode, the display 151 may additionally or alternatively display images which are associated with these modes.

A touch screen panel may be mounted upon the display 151. This configuration permits the display to function both as an output device and an input device.

The display 151 may be implemented using known display technologies including, for example, a liquid crystal display (LCD), a thin film transistor-liquid crystal display (TFT-LCD), an organic light-emitting diode display (OLED), a flexible display and a three-dimensional display. The mobile device may include one or more of such displays.

FIG. 13 further shows an output unit 150 having an audio output module 152 which supports the audio output requirements of the mobile device 100. The audio output module is often implemented using one or more speakers, buzzers, other audio producing devices, and combinations thereof. The audio output module functions in various modes including call-receiving mode, call-placing mode, recording mode, voice recognition mode and broadcast reception mode. During operation, the audio output module 152 outputs audio relating to a particular function (e.g., call received, message received, and errors).

The output unit 150 is further shown having an alarm 153, which is commonly used to signal or otherwise identify the occurrence of a particular event associated with the mobile device. Typical events include call received, message received and user input received. An example of such output includes the providing of tactile sensations (e.g., vibration) to a user. For instance, the alarm 153 may be configured to vibrate responsive to the mobile device receiving a call or message. As another example, vibration is provided by alarm 153 as a feedback responsive to receiving user input at the mobile device, thus providing a tactile feedback mechanism. It is understood that the various output provided by the components of output unit 150 may be separately performed, or such output may be performed using any combination of such components.

The memory 160 is generally used to store various types of data to support the processing, control, and storage requirements of the mobile device. Examples of such data include program instructions for applications operating on the mobile device, contact data, phonebook data, messages, pictures, video, etc. The memory 160 shown in FIG. 13 may be implemented using any type (or combination) of suitable volatile and non-volatile memory or storage devices including random access memory (RAM) static random access memory (SRAM), electrically erasable programmable read-only memory (EEPROM) erasable programmable read-only memory (EPROM), programmable read-only memory (PROM), read-only memory (ROM), magnetic memory, flash memory, magnetic or optical disk, card-type memory, or other similar memory or data storage device.

The controller 180 typically controls the overall operations of the mobile device. For instance, the controller performs the control and processing associated with voice calls, data communications, video calls, camera operations and recording operations. If desired, the controller may include a multimedia module 181 which provides multimedia playback. The multimedia module may be configured as part of the controller 180, or this module may be implemented as a separate component. As an example, the controller 180 can communicate with the controller 18 of the input unit of FIG. 2, or can perform the controlling operation of the controller 18

The power supply 190 provides power required by the various components for the portable device. The provided power may be internal power, external power, or combinations thereof.

Various embodiments described herein may be implemented in a computer-readable medium using, for example, computer software, hardware, or some combination thereof. For a hardware implementation, the embodiments described herein may be implemented within one or more application specific integrated circuits (ASICs), digital signal processors (DSPS), digital signal processing devices (DSPDs), programmable logic devices (PLDs), field programmable gate arrays (FPGAs), processors, controllers, micro-controllers, microprocessors, other electronic units designed to perform the functions described herein, or a selective combination thereof. In some cases, such embodiments are implemented by controller 180.

For a software implementation, the embodiments described herein may be implemented with separate software modules, such as procedures and functions, each of which perform one or more of the functions and operations described herein. The software codes can be implemented with a software application written in any suitable programming language and may be stored in memory (for example, memory 160), and executed by a controller or processor (for example, controller 180).

The mobile device 100 of FIG. 13 may be configured to operate within a communication system which transmits data via frames or packets, including both wireless and wireline communication systems, and satellite-based communication systems. Such communication systems utilize different air interfaces and/or physical layers.

Examples of such air interfaces utilized by the communication systems include example, frequency division multiple access (FDMA), time division multiple access (TDMA), code division multiple access (CDMA), and universal mobile telecommunications system (UMTS), the long term evolution (LTE) of the UMTS, and the global system for mobile communications (GSM). By way of non-limiting example only, further description will relate to a CDMA communication system, but such teachings apply equally to other system types.

Referring now to FIG. 14, a CDMA wireless communication system is shown having a plurality of mobile devices 100, a plurality of base stations 270, base station controllers (BSCs) 275, and a mobile switching center (MSC) 280. The MSC 280 is configured to interface with a conventional public switch telephone network (PSTN) 290. All the components of the system are operatively coupled and configured. Each mobile device 100 can include the input unit of the present invention. The MSC 280 is also configured to interface with the BSCs 275. The BSCs 275 are coupled to the base stations 270 via backhaul lines. The backhaul lines may be configured in accordance with any of several known interfaces including, for example, E1/T1, ATM, IP, PPP, Frame Relay, HDSL, ADSL, or xDSL. It is to be understood that the system may include more than two BSCs 275.

Each base station 270 may include one or more sectors, each sector having an omnidirectional antenna or an antenna pointed in a particular direction radially away from the base station 270. Alternatively, each sector may include two antennas for diversity reception. Each base station 270 may be configured to support a plurality of frequency assignments, with each frequency assignment having a particular spectrum (e.g., 1.25 MHz, 5 MHz).

The intersection of a sector and frequency assignment may be referred to as a CDMA channel. The base stations 270 may also be referred to as base station transceiver subsystems (BTSs). In some cases, the term “base station” may be used to refer collectively to a BSC 275, and one or more base stations 270. The base stations may also be denoted “cell sites.” Alternatively, individual sectors of a given base station 270 may be referred to as cell sites.

A terrestrial digital multimedia broadcasting (DMB) transmitter 295 is shown broadcasting to portable/mobile devices 100 operating within the system. The broadcast receiving module 111 (FIG. 13) of the portable device is typically configured to receive broadcast signals transmitted by the DMB transmitter 295. Similar arrangements may be implemented for other types of broadcast and multicast signaling (as discussed above).

FIG. 14 further depicts several global positioning system (GPS) satellites 297. Such satellites facilitate locating the position of some or all of the portable devices 100. Two satellites are depicted, but it is understood that useful positioning information may be obtained with greater or fewer satellites. The position-location module 115 (FIG. 13) of the portable device 100 is typically configured to cooperate with the satellites 297 to obtain desired position information. It is to be appreciated that other types of position detection technology, (i.e., location technology that may be used in addition to or instead of GPS location technology) may alternatively be implemented. If desired, some or all of the GPS satellites 297 may alternatively or additionally be configured to provide satellite DMB transmissions.

During typical operation of the wireless communication system, the base stations 270 receive sets of reverse-link signals from various mobile devices 100. The mobile devices 100 are engaging in calls, messaging, and other communications. Each reverse-link signal received by a given base station 270 is processed within that base station. The resulting data is forwarded to an associated BSC 275. The BSC provides call resource allocation and mobility management functionality including the orchestration of soft handoffs between base stations 270. The BSCs 275 also route the received data to the MSC 280, which provides additional routing services for interfacing with the PSTN 290. Similarly, the PSTN interfaces with the MSC 280, and the MSC interfaces with the BSCs 275, which in turn control the base stations 270 to transmit sets of forward-link signals to the mobile devices 100.

In various examples, the image processor and/or controller of the input unit can analyze the captured images and determine if an input is made. Further, the image processor and the controller can be integrated into one unit or can be separate units. Also, these terms may be interchangeably used.

Although embodiments have been described with reference to a number of illustrative embodiments thereof, it should be understood that numerous other modifications and embodiments can be devised by those skilled in the art that will fall within the spirit and scope of the principles of this disclosure.

What is claimed is:

1. An input unit comprising:
a pattern generator including at least first and second light sources, the first light source configured to generate an imaging light for displaying an input pattern, the second light source configured to generate a detection light;
an image receiver configured to receive and process an image of an input member over the input pattern and a shadow image of the input member using the detection light; and
a controller configured to perform an operation based on information of the image of the input member and the shadow image processed by the image receiver.

2. The input unit according to claim 1, wherein the pattern generator further comprises:
a space light modulator (SLM) configured to modulate the light from the first light source so as to generate the input pattern; and
a beam splitter configured to receive and process the modulated light from the SLM and the detection light from the second light source, and to output the input pattern and the detection light overlapping each other.

3. The input unit according to claim 1, wherein the pattern generator further comprises:
a first space light modulator (SLM) configured to modulate the imaging light from the first light source; and
a second SLM configured to modulate the detection light from the second light source.

4. The input unit according to claim 3, wherein the pattern generator further comprises:
at least one lens disposed before the first and second SLMs.

5. The input unit according to claim 3, wherein the pattern generator further comprises:
at least one lens disposed after the first and second SLMs.

6. The input unit according to claim 3, wherein the first and second SLMs are aligned with each other.

7. The input unit according to claim 1, wherein the pattern generator further comprises:
a space light modulator (SLM) configured to modulate the imaging light from the first light source to generate the input pattern; and
a reflecting layer disposed in front of the SLM and configured to reflect the detection light impinging thereon and to transmit the imaging light impinging thereon towards the SLM.

8. The input unit according to claim 7, wherein the SLM is a reflective type SLM for reflectively outputting the modulated imaging light.

9. The input unit according to claim 1, wherein the detection light comprises markers for detecting a position of the input member and/or a distortion in the input pattern.

10. The input unit according to claim 1, wherein the imaging light is in a visible light band, and the detection light is in an invisible light band.

11. An input unit comprising:
a pattern generator including first and second light sources respectively generating an imaging light and a detection light, the pattern generator further including a reflecting mechanism for reflecting the imaging light and the detection light , the imaging light displaying an input pattern;
an image receiver configured to capture an image of an input member over the input pattern and a shadow image of the input member using the detection light; and
a controller configured to determine if the input member falls within a contact range of the input pattern using information of the captured image of the input member and the captured shadow image, and to perform an operation based on the determination result.

12. The input unit according to claim 11, wherein the reflecting mechanism includes:
a reflective type space light modulator for reflecting the imaging light from the first light source, and
a reflector provided in front of the space light modulator, for reflecting the detection light from the second light source.

13. The input unit according to claim 11, wherein the space light modulator modulates the imaging light to selectively change a size and/or pattern of the input pattern.

14. The input unit according to claim 11, wherein the detection light comprises markers for detecting a position of the input member and/or a distortion in the input pattern.

15. A mobile device comprising:
a wireless communication unit configured to perform wireless communication with a wireless communication system or another device;
an input unit configured to receive an input, and including
a pattern generator including at least first and second light sources, the first light source configured to generate an imaging light for displaying an input pattern, the second light source configured to generate a detection light,
an image receiver configured to receive and process an image of an input member over the input pattern and a shadow image of the input member using the detection light, and
a controller configured to perform an operation based on information of the image of the input member and the shadow image processed by the image receiver;
a display unit configured to display information including the input received by the input unit; and
a storage unit configured to store the input pattern.

16. The mobile device according to claim 15, wherein the pattern generator of the input unit further comprises:
a space light modulator (SLM) configured to modulate the light from the first light source so as to generate the input pattern; and
a beam splitter configured to receive and process the modulated light from the SLM and the detection light from the second light source, and to output the input pattern and the detection light overlapping each other.

17. The mobile device according to claim 15, wherein the pattern generator of the input unit further comprises:
a first space light modulator (SLM) configured to modulate the imaging light from the first light source; and
a second SLM configured to modulate the detection light from the second light source.

18. The mobile device according to claim 17, wherein the pattern generator of the input unit further comprises:
at least one lens disposed before the first and second SLMs.

19. The mobile device according to claim 17, wherein the pattern generator of the input unit further comprises:
at least one lens disposed after the first and second SLMs.

20. The mobile device according to claim 17, wherein the first and second SLMs are aligned with each other.

21. The mobile device according to claim 15, wherein the pattern generator of the input unit further comprises:
a space light modulator (SLM) configured to modulate the imaging light from the first light source to generate the input pattern; and
a reflecting layer disposed in front of the SLM and configured to reflect the detection light impinging thereon and to transmit the imaging light impinging thereon towards the SLM.

22. The mobile device according to claim 21, wherein the SLM is a reflective type SLM for reflectively outputting the modulated imaging light.

23. The mobile device according to claim 15, wherein the detection light comprises markers for detecting a position of the input member and/or a distortion in the input pattern.
